(19) United States
(12) Patent Application Publication
(10) Pub. No.: US 2026/0123329 A1
(43) Pub. Date: Apr. 30, 2026

(54) SUBSTRATE PROCESSING APPARATUS AND SUBSTRATE PROCESSING METHOD

(71) Applicant: SCREEN Holdings Co., Ltd., Kyoto (JP)

(72) Inventors: Akihiro NAKASHIMA, Kyoto (JP); Shoya FUKUMOTO, Kyoto (JP)

(21) Appl. No.: 19/366,449

(22) Filed: Oct. 22, 2025

(30) Foreign Application Priority Data
Oct. 30, 2024 (JP) 2024-191033

(51) Int. Cl. H01L 21/67; C03C 15/00; H01L 21/306

(52) U.S. Cl. CPC H10P 72/0424; C03C 15/00; H10P 50/642

(57) ABSTRACT

A configuration of a substrate processing apparatus is downsized while enabling design of a pressure sensor into a desired shape in a space between an actuator and a nozzle body. A processing unit includes: a nozzle body configured to discharge a processing liquid toward a peripheral portion of a lower surface of a substrate; a shaft configured to advance and retract in a radial direction of the substrate by driving of a motor; a pressure sensor configured to obtain a pressure value caused between the motor and the nozzle body; and an origin position detection part configured to, when the pressure value becomes equal to or greater than a predetermined threshold, detect that the nozzle body has returned to its origin.

### DESCRIPTION

This Nonprovisional application claims priority under 35 U.S.C. §119 on Patent Application No. 2024-191033 filed in Japan on October 30, 2024, the entire contents of which are hereby incorporated by reference.

### Technical Field

The present invention relates to a substrate processing apparatus and a substrate processing method.

### Background Art

Processes on circular or substantially circular substrates, such as semiconductor wafers, include removal of only a thin film at a peripheral portion of a substrate from the thin film formed on at least one main surface of the substrate. For example, a technique is known in which by supplying an etching liquid to a peripheral portion of a substrate while rotating the substrate, only a thin film on an outer side of a position to which the etching liquid is supplied is removed. The process of removing the thin film as described above may be referred to as bevel etching process.

For example, Patent Literature 1 discloses a configuration in which in a substrate processing apparatus accommodated in a processing chamber, for an etching process on a peripheral portion of a lower surface of the substrate in a horizontal position, a lower peripheral nozzle is provided below the substrate. This lower peripheral nozzle is provided with a plurality of nozzles at a nozzle support member, and each of the nozzles discharges a processing liquid, such as a chemical liquid or a rinse agent, upward toward a peripheral portion of the lower surface of the substrate.

### Citation List

### Patent Literature

Patent Literature 1

Japanese Patent Application Publication Tokukai No. 2022-052835

### SUMMARY OF INVENTION

### Technical Problem

However, Patent Literature 1 does not disclose the details of an attachment structure of the nozzles to the nozzle support member. Therefore, it is unclear how to adjust positions of the nozzles in the substrate processing apparatus disclosed in Patent Literature 1. In addition, if in the substrate processing apparatus, the positions of the nozzles are adjustable, it is necessary to ensure a space for adjusting the positions of the nozzles.

It is an object of an aspect of the present invention to downsize a configuration of a substrate processing apparatus while enabling design of a pressure sensor into a desired shape in a space between an actuator and a nozzle body.

### Solution to Problem

In order to solve the foregoing problem, a substrate processing apparatus in accordance with an aspect of the present invention includes: a rotator configured to retain a substrate with a circular shape in a horizontal position and rotate the substrate about a vertical axis passing the center of the substrate; a nozzle body disposed below the substrate and configured to discharge a processing liquid from a discharge port thereof toward a peripheral portion of a lower surface of the substrate; a shaft having one end connected to the nozzle body and the other end connected to an actuator, the shaft advancing and retracting in a radial direction of the substrate by driving of the actuator; a pressure sensor configured to obtain a pressure value caused between the actuator and the nozzle body by movement of the nozzle body in the radial direction of the substrate while the nozzle body is being guided by the shaft; and an origin position detection part configured to, when the pressure value becomes equal to or greater than a predetermined threshold, detect that the nozzle body has returned to an origin thereof.

A substrate processing method in accordance with an aspect of the present invention includes: using a rotator to, while retaining a substrate with a circular shape in a horizontal position, rotate the substrate about a vertical axis passing the center of the substrate; causing a shaft to advance and retract in a radial direction of the substrate by driving of an actuator, the shaft having one end connected to a nozzle body disposed below the substrate so that a processing liquid is discharged from a discharge port thereof toward a peripheral portion of a lower surface of the substrate and the other end connected to the actuator; and obtaining, with use of a pressure sensor, a pressure value caused between the actuator and the nozzle body by movement of the nozzle body in the radial direction of the substrate while the nozzle body is being guided by the shaft, the nozzle body being, when the pressure value becomes equal to or greater than a predetermined threshold, detected to have returned to an origin thereof.

### Advantageous Effects of Invention

According to an aspect of the present invention, it is possible to downsize a configuration of a substrate processing apparatus while enabling design of a pressure sensor into a desired shape in a space between an actuator and a nozzle body.

### BRIEF DESCRIPTION OF DRAWINGS

FIG. 1 is a plan view illustrating a schematic configuration of a substrate processing system equipped with an embodiment of a processing unit in accordance with an aspect of a substrate processing apparatus in accordance with the present invention.

FIG. 2 is a side view illustrating an internal structure of a processing unit.

FIG. 3 is a plan view illustrating the processing unit illustrated in FIG. 2.

FIG. 4 is a view illustrating a structure and arrangement of a processing mechanism included in the processing unit.

FIG. 5 is a cross-sectional view of a nozzle block, illustrating a structure of one processing liquid discharge nozzle part included in a processing mechanism, and shows a situation in which a nozzle body is located at its origin.

FIG. 6 is a cross-sectional view of a nozzle block, illustrating a structure of one processing liquid discharge nozzle part included in a processing mechanism, and shows a situation in which a nozzle body has advanced the furthest.

FIG. 7 is a perspective view illustrating a configuration in the vicinity of a pressure sensor included in a processing mechanism.

FIG. 8 is a flowchart illustrating one example of a process in which a control unit included in a processing unit causes a nozzle body to discharge a processing liquid.

FIG. 9 is a flowchart illustrating one example of a process in which a control unit included in a processing unit causes a nozzle body to move.

FIG. 10 is a graph illustrating one example of a relationship between time and a pressure value obtained by a pressure sensor.

FIG. 11 is each graph illustrating one example of a relationship between time and pressure values at a plurality of pressure detection points obtained by a pressure sensor.

FIG. 12 is a cross-sectional view illustrating a nozzle block included in a processing unit in accordance with variation 1 of the present invention.

FIG. 13 is a cross-sectional view illustrating an example of an open/close valve included in a processing unit in accordance with variation 2 of the present invention.

### DESCRIPTION OF EMBODIMENTS

### Substrate processing system

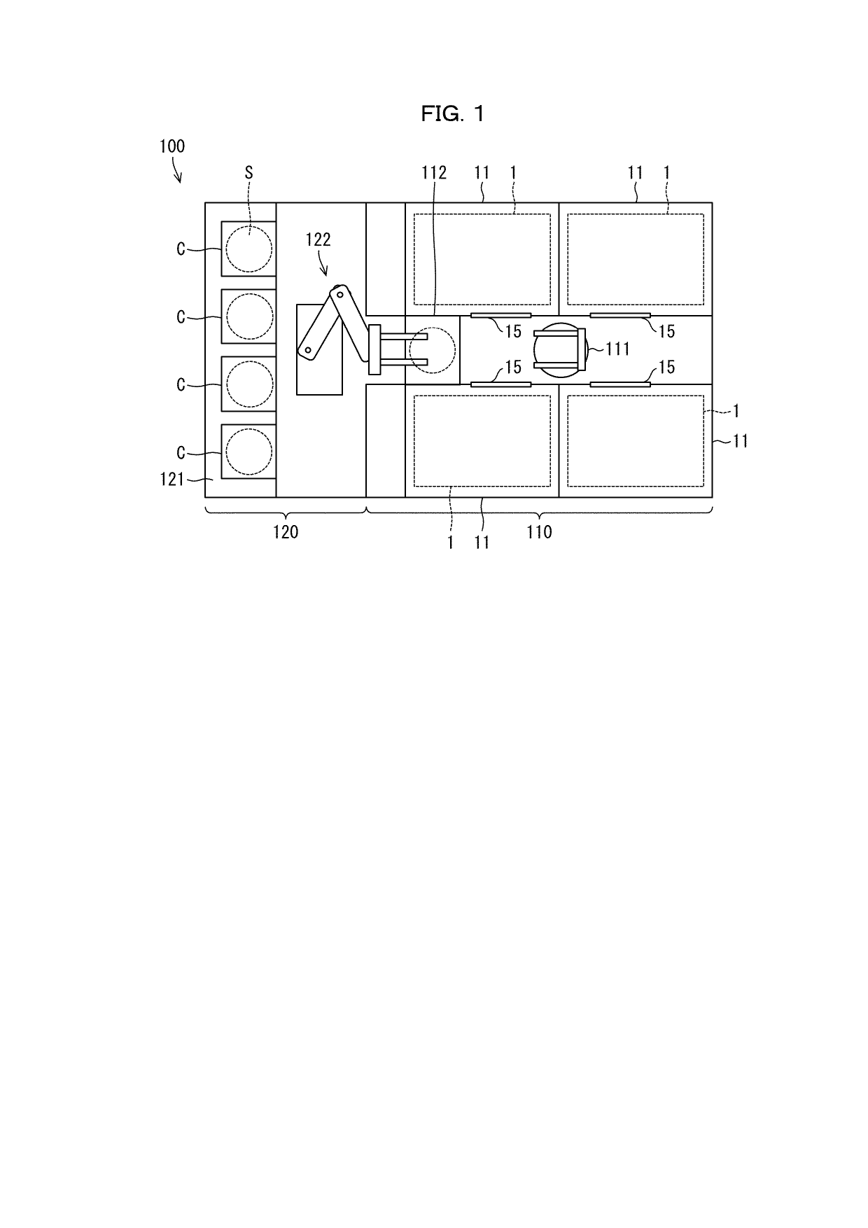

The following description will discuss an embodiment of the present invention in detail. The following will mainly provide a description on a substrate processing system, but the description also includes explanation for a substrate processing method for processing a substrate. FIG. 1 is a plan view illustrating a schematic configuration of a substrate processing system 100 equipped with an embodiment of a processing unit 1 in accordance with an aspect of a substrate processing apparatus in accordance with the present invention. FIG. 1 is a schematic view illustrating the internal structure of the substrate processing system 100 with outer wall panels thereof and some of the other components omitted for better visibility. This substrate processing system 100 is, for example, a single wafer-type apparatus that processes substrates S one by one and that is installed in a clean room.

The substrate processing system 100 includes a plurality of processing units (substrate processing apparatuses) 1 each serving as a main processing entity for the substrate S. FIG. 1 shows that the four processing units 1 are disposed in a horizontal direction, but the processing units 1 can be also stacked in layers in an up-and-down direction. In each of the plurality of processing units 1 included in the substrate processing system 100, a substrate is processed with use of a processing liquid.

The substrate S is a substrate with a circular shape. It should be noted that in the present embodiment, the "substrate with a circular shape" encompasses not only a substrate whose main surface is strictly circular in plan view but also a "substrate with a substantially circular shape" that has a circular envelope shape but has portions, such as orientation flats or notches, which deviate from the circular periphery.

Examples of the "substrate" in the present embodiment include various substrates such as semiconductor wafers, glass substrates for photomasks, glass substrates for liquid crystal displays, glass substrates for plasma displays, substrates for field emission displays (FEDs), substrates for optical disks, substrates for magnetic disks, and substrates for magneto-optical disks. The following will provide descriptions with reference to the drawings by taking a substrate processing apparatus used for processing a semiconductor wafer as a main example, but the same descriptions are applicable to the processes on the various substrates mentioned above as examples.

The processing units 1 in accordance with the present embodiment each carry out a process of receiving a substrate S having one main surface on which a thin film of metal or a metal compound and removing only a peripheral portion of the thin film formed on the substrate S by an etching process. Such an etching process may be referred to as "bevel etching process" or simply as "bevel process". An aspect may be employed in which all of the plurality of processing units 1 included in the substrate processing system 100 are configured to carry out such a bevel etching process, or a plurality of types of processing units that carry out different processes may be combined.

As illustrated in FIG. 1, the substrate processing system 100 has a substrate processing area 110 where the substrate S is processed. An indexer part 120 is provided adjacent to this substrate processing area 110. The indexer part 120 has a container retaining part 121 capable of retaining a plurality of containers C each for accommodating the substrate S. The indexer part 120 includes an indexer robot 122 configured to access a container C retained by the container retaining part 121 to take a substrate S that has not been processed out of the container C and store a substrate S that has been processed into the container C. Each container C accommodates a plurality of substrates S in a substantially horizontal position.

A placement table 112 is provided in the substrate processing area 110 so as to enable a substrate S to be placed thereon from the indexer robot 122. Substantially at the center of the substrate processing area 110 in a plan view, a substrate transfer robot 111 is disposed. The plurality of processing units 1 are disposed so as to surround this substrate transfer robot 111.

The substrate transfer robot 111 randomly accesses the placement table 112 and transfers a substrate S between each of these processing units 1 and the placement table 112. Each processing unit 1 is configured to carry out a predetermined process on the substrate S and corresponds to the substrate processing apparatus in accordance with the present invention. In the present embodiment, these processing units (substrate processing apparatuses) 1 have the same function. Therefore, it is possible to carry out the processes on a plurality of substrates S in parallel. Note that the reference sign 11 in FIG. 1 represents a chamber serving as a partition wall of the processing unit 1, and a member denoted by the reference sign 15 represents a shutter provided to the chamber 11.

### Interior of processing unit

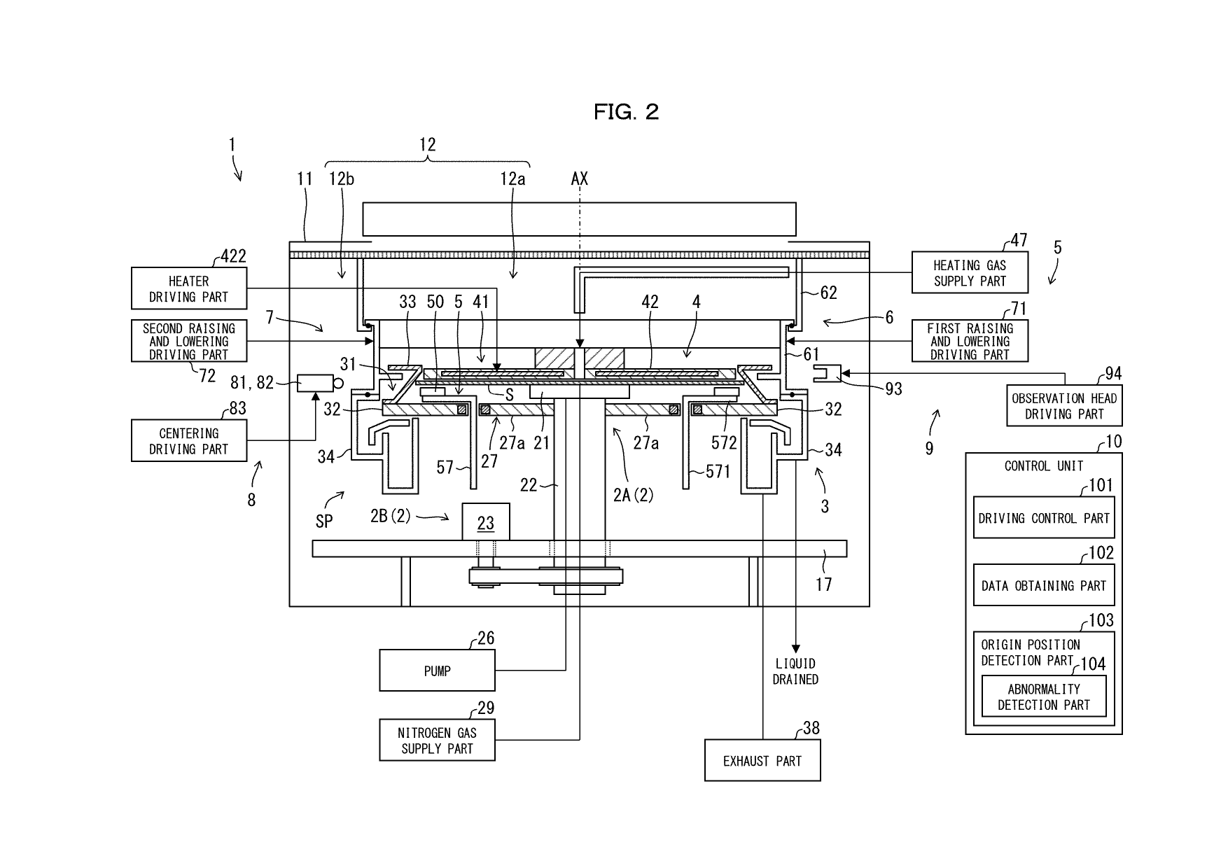

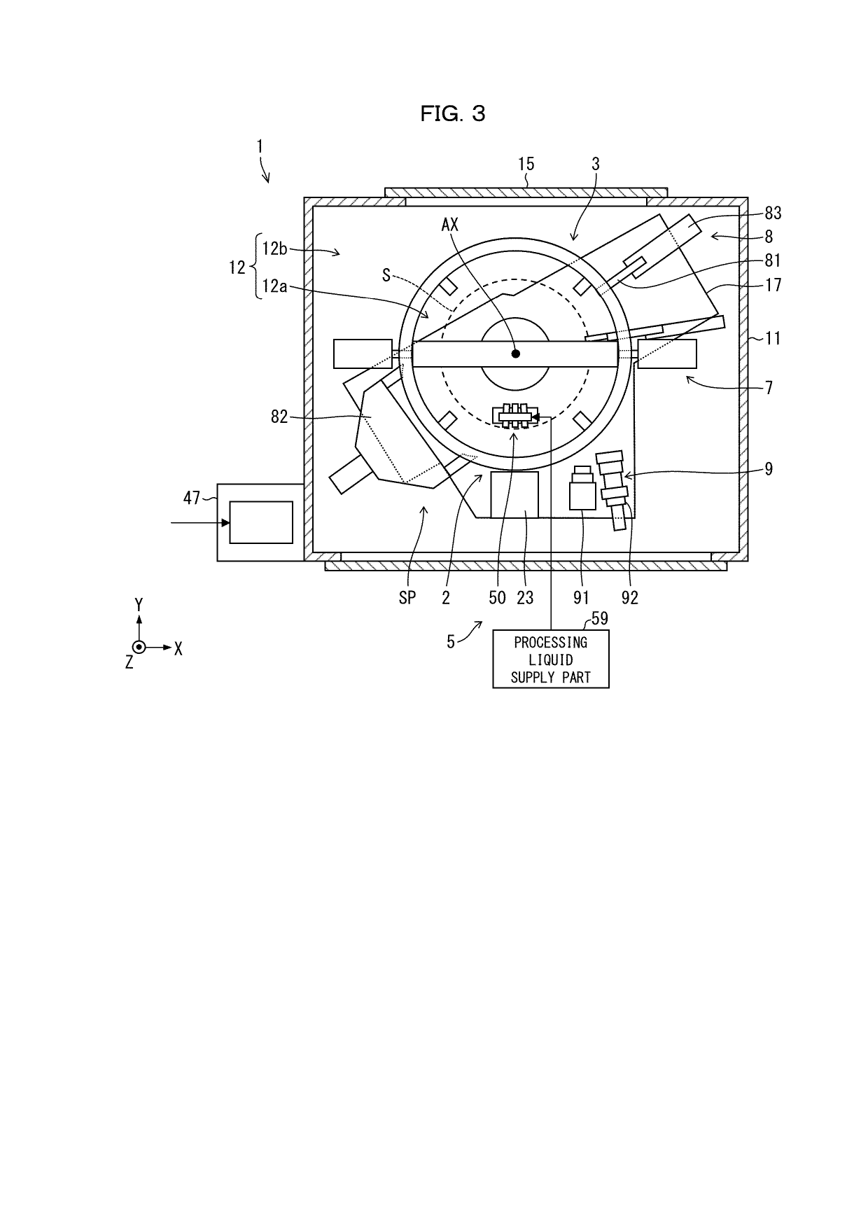

FIG. 2 is a side view illustrating an internal configuration of each processing unit 1, and FIG. 3 is a plan view illustrating the processing unit 1 in FIG. 2. For ease of understanding, the dimensions and the numbers of the components may be exaggerated or simplified in FIG. 2 and FIG. 3.

As illustrated in FIG. 2 and FIG. 3, the processing unit 1 has a structure in which a substrate processing section SP is disposed in an interior space 12 inside the chamber 11. The substrate processing section SP included in the processing unit 1 is installed on an upper surface of a base member 17 having a raised floor structure. Each component of the substrate processing section SP is electrically connected to a control unit 10 that controls the entire apparatus and operates in accordance with an instruction from the control unit 10.

In the following description, in order to clarify, for example, the arrangement relationships between and operations of the components of the apparatus, a coordinate system is defined as appropriate in which the Z direction represents the vertical direction and the XY plane represents the horizontal plane. In the coordinate system in FIG. 3, the horizontal direction corresponding to the up-and-down direction on the drawing is defined as "Y direction", and the horizontal direction orthogonal thereto is defined as "X direction".

The substrate processing section SP includes a retaining and rotating mechanism 2, an anti-scattering mechanism 3, an upper-surface protecting and heating mechanism 4, a processing mechanism 5, an atmosphere separating mechanism 6, a raising and lowering mechanism 7, a centering mechanism 8, and a substrate observing mechanism 9. These mechanisms are provided on the base member 17.

The retaining and rotating mechanism (rotator (rotating mechanism)) 2 is configured to retain the substrate S in a horizontal position and rotate the substrate S about a vertical axis passing the center of the substrate S. The retaining and rotating mechanism 2 includes a substrate retaining part 2A that retains the substrate S in a substantially horizontal position with a film forming surface of the substrate S facing downward and a rotating mechanism part 2B that rotates the substrate retaining part 2A retaining the substrate S and a rotation cup part 31 that is one component of the anti-scattering mechanism 3 in synchronization.

The substrate retaining part 2A includes a spin chuck 21 which is a disk-shaped member smaller than the substrate S. The spin chuck 21 is provided so that the center axis thereof is aligned with a rotation axis AX, and is configured to retain the substrate S by suction from below through the suction force of a pump 26. The spin chuck 21 is supplied with nitrogen gas at normal temperature from a nitrogen gas supply part 29.

To the lower surface of the spin chuck 21, a rotation shaft part 22 that has a cylindrical shape is coupled. The rotation shaft part 22 is provided so as to extend in the vertical direction Z so that the axis thereof is aligned with the rotation axis AX. To the rotation shaft part 22, the rotating mechanism part 2B is connected.

The rotating mechanism part 2B includes a motor 23 that generates a rotational driving force for rotating the substrate retaining part 2A and the rotation cup part 31 of the anti-scattering mechanism 3, and a force transmission part 27 configured to transmit the rotational driving force.

The rotating mechanism part 2B has the force transmission part 27 in order to not only rotate the spin chuck 21 integrally with the substrate S but also rotate the rotation cup part 31 in synchronization with the rotation. The force transmission part 27 has a disk member 27a made of a non-magnetic material or resin. The disk member 27a is provided coaxially with the rotation shaft part 22, and is rotatable about the rotation axis AX together with the rotation shaft part 22.

The anti-scattering mechanism 3 is configured to prevent the etching liquid discharged in an etching process from scattering, and recover the liquid after the process. The anti-scattering mechanism 3 includes the rotation cup part 31 rotatable about the rotation axis AX while surrounding the outer periphery of the substrate S retained by the spin chuck 21, and a fixed cup part 34 provided in a fixed state so as to surround the rotation cup part 31. The rotation cup part 31 is a coupled body in which a lower cup 32 and an upper cup 33 are coupled. Droplets collected by the rotation cup part 31 are recovered together with the gas component and are gathered in the fixed cup part 34. The droplets are drained, and the gas component is efficiently let out by adjustment of the pressure of the fixed cup part 34 by the operation by an exhaust part 38.

The upper-surface protecting and heating mechanism 4 is configured to prevent the upper surface of the substrate S from being exposed to the surrounding atmosphere to protect the upper surface. The upper-surface protecting and heating mechanism 4 has a blocking plate 41 disposed above the upper surface of the substrate S retained by the spin chuck 21, and the blocking plate 41 has a disk part 42 retained in a horizontal position. The disk part 42 contains an unillustrated heater that is driven and controlled by a heater driving part 422.

With the disk part 42 positioned in a processing position in the vicinity of the substrate S, the upper-surface protecting and heating mechanism 4 supplies heating gas between the substrate S and the disk part 42 from a heating gas supply part 47. The heating gas is supplied from a center side of the disk part 42 and then flows toward the peripheral portion thereof. This prevents the atmosphere surrounding the substrate S from penetrating to the upper surface of the substrate S.

The atmosphere separating mechanism 6 is configured to separate the interior space 12 of the chamber 11 into an enclosed space 12a where the bevel process can be carried out on the substrate S and an outer space 12b of the enclosed space 12a. The atmosphere separating mechanism 6 is disposed so as to fully surround the spin chuck 21, the substrate S retained by the spin chuck 21, the rotation cup part 31, and the upper-surface protecting and heating mechanism 4 from above. The atmosphere separating mechanism 6 includes a lower enclosing cup member 61 and an upper enclosing cup member 62. The lower enclosing cup member 61 is provided so as to be movable in the vertical direction (movable upward and downward).

As illustrated in FIG. 2, the lower enclosing cup member 61 is lowered to be positioned in a lower limit position, so that the upper enclosing cup member 62, the lower enclosing cup member 61, and the fixed cup part 34 are connected to each other in the vertical direction, thereby forming the enclosed space 12a by the upper enclosing cup member 62, the lower enclosing cup member 61, and the fixed cup part 34.

Although not illustrated, when the lower enclosing cup member 61 moves upward to a retraction position, the upper cup 33 also moves upward in engagement with the lower enclosing cup member 61. This causes the upper cup 33 and the upper-surface protecting and heating mechanism 4 to move upward away from the spin chuck 21. The movement of the lower enclosing cup member 61 to the retraction position forms a transfer space for the hand of the substrate transfer robot 111 to access the spin chuck 21.

The raising and lowering mechanism 7 is configured to cause the lower enclosing cup member 61 described above to move upward and downward. The raising and lowering mechanism 7 includes two raising and lowering driving parts: a first raising and lowering driving part 71 and a second raising and lowering driving part 72. The first raising and lowering driving part 71 and the second raising and lowering driving part 72 cause different two portions of the side surface of the lower enclosing cup member 61 in a circumferential direction thereof to move in the vertical direction in synchronization. Therefore, it is possible to stably raise and lower the upper-surface protecting and heating mechanism 4 and the lower enclosing cup member 61. The raising and lowering mechanism 7 also raises and lowers the upper cup 33 that is coupled to the lower cup 32 to form the rotation cup part 31, in accordance with the raising and lowering of the lower enclosing cup member 61.

The centering mechanism 8 is configured to carry out a centering process of eliminating an eccentric state of the substrate S to align the center of the substrate S with the rotation axis AX. The centering mechanism 8 includes a single-contact part 81 and a multi-contact part 82 disposed on opposite sides with the rotation axis AX of the spin chuck 21 interposed therebetween, and a centering driving part 83 that causes the single-contact part 81 and the multi-contact part 82 to move in a movement direction for contact.

The substrate observing mechanism 9 is a mechanism for optically observing a peripheral portion of a substrate S that is a process target, in order to check whether the process is being appropriately carried out. The substrate observing mechanism 9 includes a light source part 91, an imaging part 92, an observation head 93, and an observation head driving part 94.

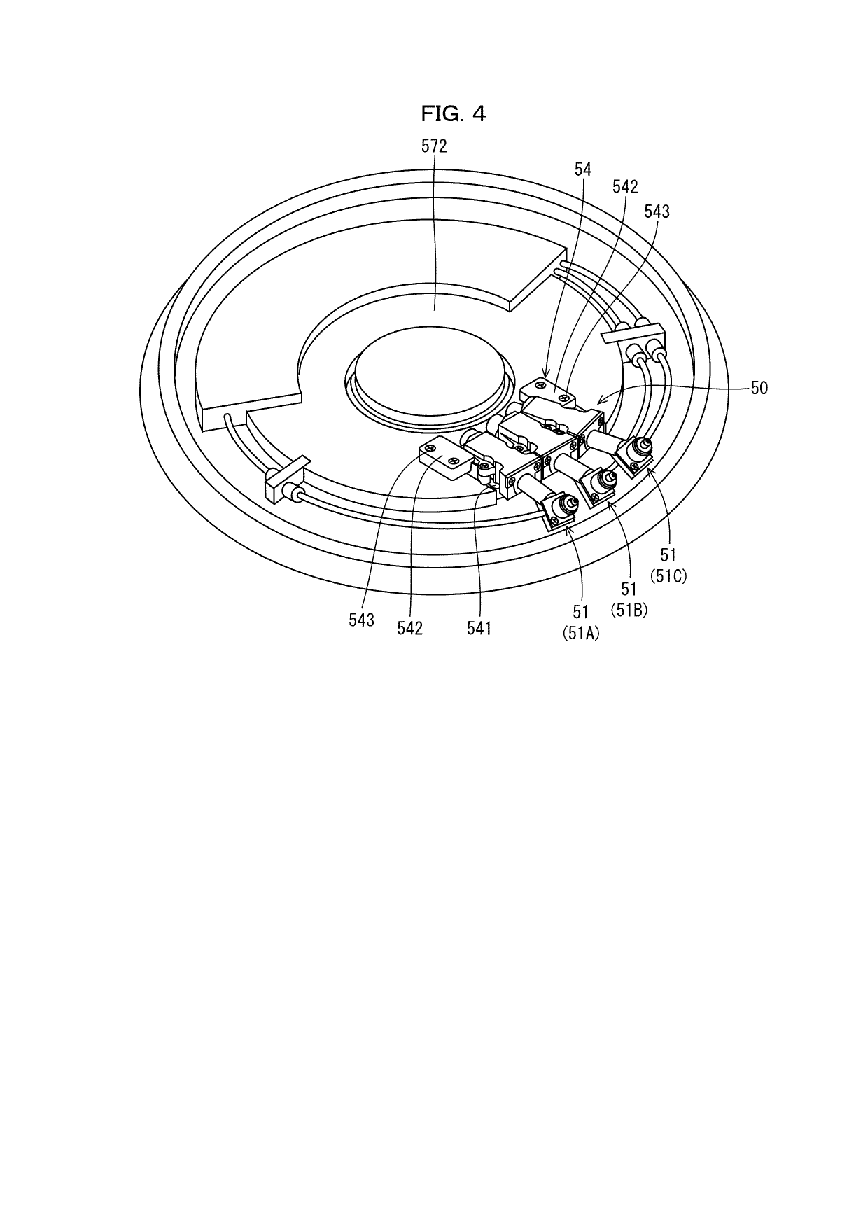

The processing mechanism 5 is configured to carry out a process of removing only the peripheral portion of the thin film formed on the substrate S by an etching process. As illustrated in FIG. 3, the processing mechanism 5 includes a nozzle block 50 disposed on a lower surface side of the substrate S and a processing liquid supply part 59 that supplies a processing liquid to the nozzle block 50. As will be described later, the nozzle block 50 includes a plurality of processing liquid discharge nozzle parts 51 (see FIG. 4), and the processing liquid supply part 59 is connected to each processing liquid discharge nozzle part 51.

The processing liquid supply part 59 is configured to be capable of supplying a chemical liquid, such as SC1 liquid and diluted hydrofluoric acid (DHF), or functional water (e.g., CO₂ water) as a processing liquid, and allows the SC1 liquid, DHF, and functional water to be discharged from the processing liquid discharge nozzle parts 51 independently of each other.

As illustrated in FIG. 2, in order to discharge the processing liquid toward a peripheral portion of the lower surface of the substrate S, a nozzle support part 57 supporting the nozzle block 50 is provided below the substrate S retained by the spin chuck 21. The nozzle support part 57 has a thin cylindrical portion 571 extending in the vertical direction and a flange portion 572 having an annular shape that is unfolded radially outward at an upper end part of the cylindrical portion 571.

The cylindrical portion 571 has a shape that can be loosely inserted freely into an air gap formed between the disk member 27a and the lower cup 32. The nozzle support part 57 is fixedly disposed so that the cylindrical portion 571 is loosely inserted into the air gap and the flange portion 572 is positioned between the substrate S retained by the spin chuck 21 and the lower cup 32. The nozzle block 50 is attached to part of a peripheral portion of the upper surface of the flange portion 572.

### Processing mechanism

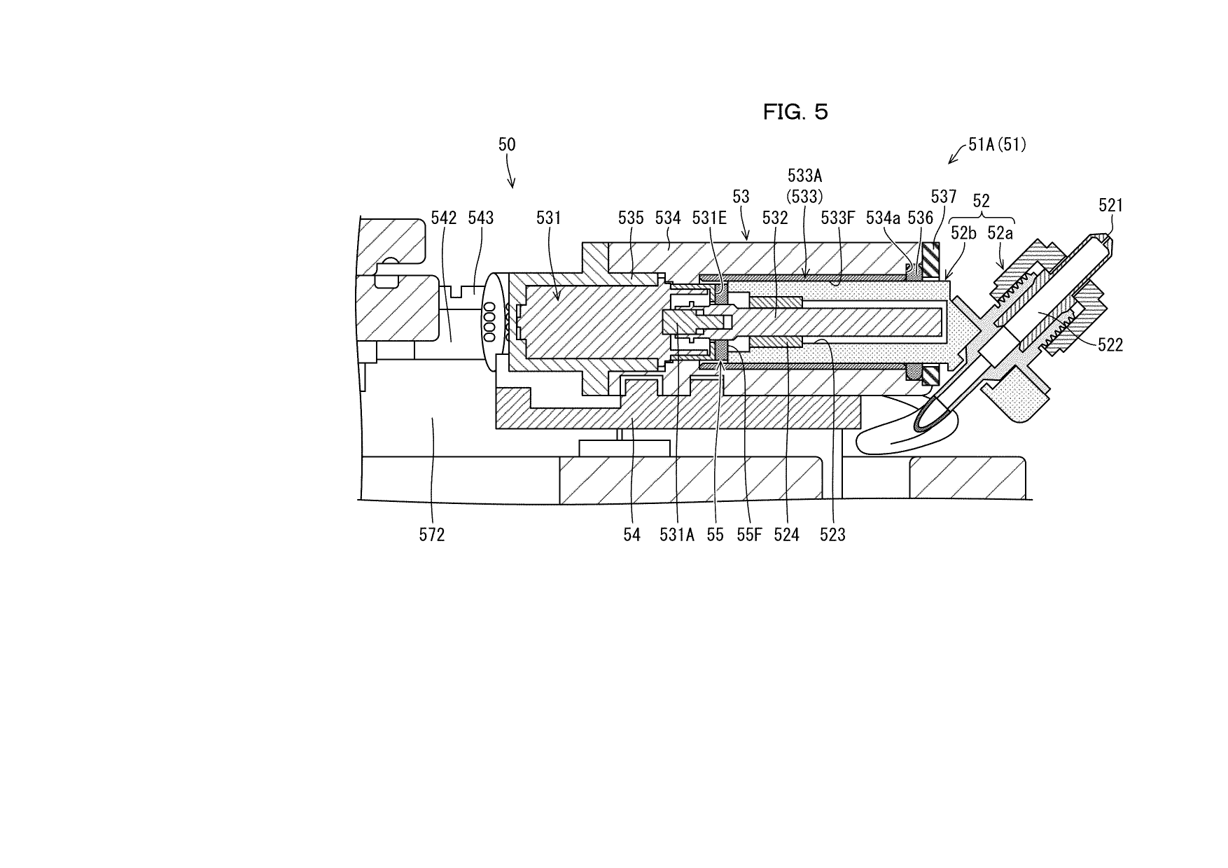

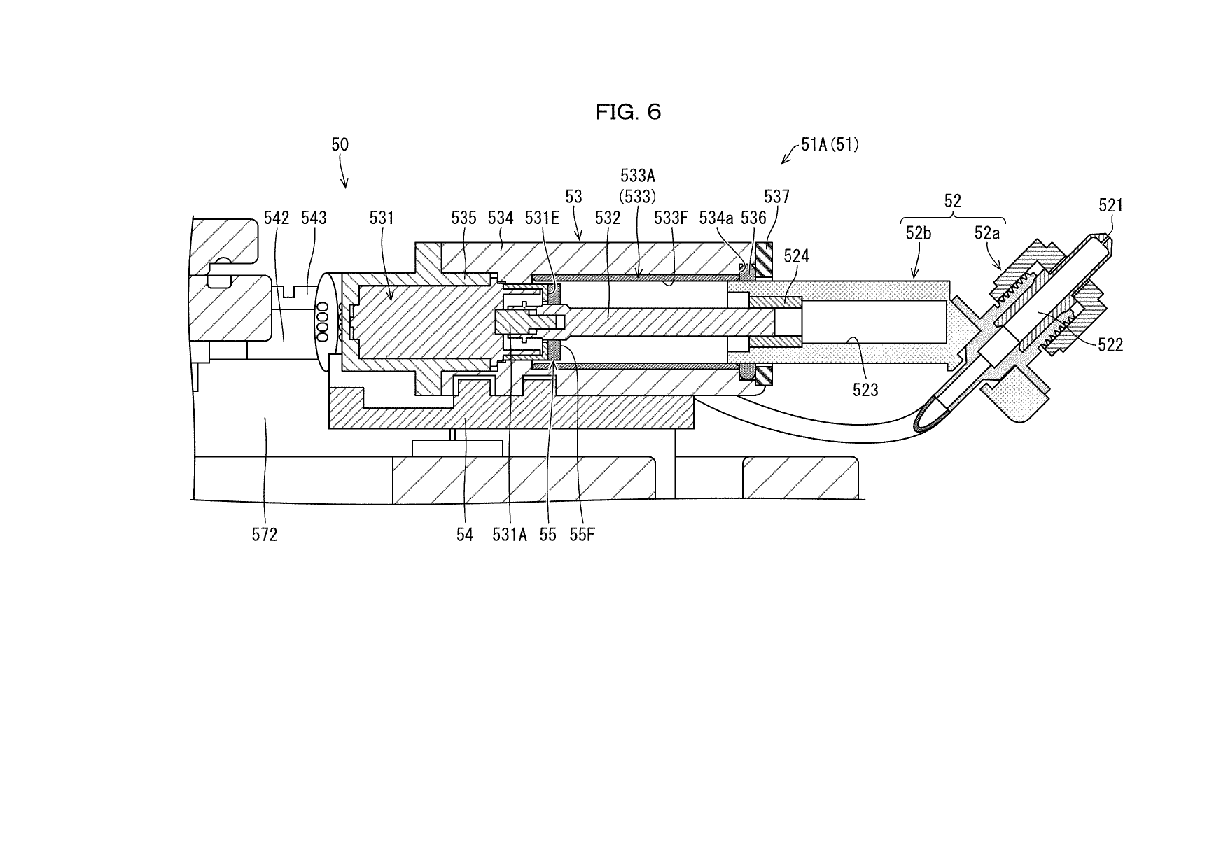

Next, with reference to FIGS. 4 to 6, the following will describe the processing mechanism 5 in detail. FIG. 4 is a view illustrating a structure and arrangement of the processing mechanism 5 included in the processing unit 1. FIG. 5 is a cross-sectional view of a nozzle block, illustrating a structure of one processing liquid discharge nozzle part included in the processing mechanism 5, and shows a situation in which a nozzle body is located at its origin. FIG. 6 is a cross-sectional view of a nozzle block, illustrating a structure of one processing liquid discharge nozzle part included in the processing mechanism 5, and shows a situation in which a nozzle body has advanced the furthest.

As illustrated in FIG. 4, the nozzle block 50 includes three paired processing liquid discharge nozzle parts 51A, 51B, and 51C that each discharge a processing liquid and a support base 54 that supports these. The processing liquid discharge nozzle parts 51A to 51C have the same shape. Although a configuration in which the nozzle block 50 includes three processing liquid discharge nozzle parts 51 is illustrated as an example here, it is sufficient that the nozzle block 50 includes two or more processing liquid discharge nozzle parts 51.

The support base 54 is attached to the substantially annular flange portion 572 provided to an upper portion of the nozzle support part 57 (see FIG. 2). The single support base 54 supports the three processing liquid discharge nozzle parts 51A to 51C. Hereinafter, a direction in which the three processing liquid discharge nozzle parts 51A to 51C are arranged is referred to as a lateral direction of the support base 54.

The support base 54 has, at both the end parts thereof in the lateral direction, ear parts 542 provided with screw holes. The support base 54 is fixed, with both the ear parts 542 in contact with the upper surface of the flange portion 572, to the flange portion 572 with use of screws 543 inserted into the screw holes formed in the ear parts 542.

A base upper surface 541 between both the ear parts 542 of the support base 54 serves as a support surface for supporting the three processing liquid discharge nozzle parts 51A to 51C. The three processing liquid discharge nozzle parts 51A to 51C are fixed to the support base 54 with use of, for example, screws.

Here, with reference to FIGS. 5 and 6, the structure of each processing liquid discharge nozzle part will be described taking one processing liquid discharge nozzle part 51A as an example. In the following description, when it is unnecessary to distinguish between the processing liquid discharge nozzle parts 51A to 51C, they may be each referred to simply as "processing liquid discharge nozzle part 51".

As illustrated in FIGS. 5 and 6, the processing liquid discharge nozzle part 51 includes a nozzle body 52 that serves as a main component of the processing liquid discharge nozzle part 51 and a nozzle driving part 53 that causes the nozzle body 52 to reciprocate in a radial direction of the substrate S. The nozzle body 52 is disposed below the substrate S and is configured to discharge the processing liquid from a discharge port 521 thereof toward a peripheral portion of the lower surface of the substrate S. The nozzle body 52 is an example of a surface processing mechanism configured to carry out a predetermined surface treatment on the substrate S.

The nozzle body 52, which has an elongated shape along a radial direction of the substrate S, has a nozzle head part 52a on a radially outer side and has a shaft-shaped part 52b on a radially inner side. The discharge port 521 that discharges a processing liquid is provided at a tip end which is a radially outer end part of the nozzle head part 52a. The discharge port 521 discharges the processing liquid supplied from the processing liquid supply part 59 (see FIG. 3) through an interior manifold part 522, obliquely upward at an elevation angle of 45 degrees and outward as seen from the rotation axis AX. The processing liquid is discharged toward a peripheral portion of the lower surface of the substrate S.

A metal thin film or a metal compound thin film is formed on the lower surface of the substrate S. In a case where the processing liquid to be discharged exhibits solubility in the coating film, a thin film on the lower surface of the substrate S in an area to which the processing liquid has adhered is removed by etching. Rotation of the substrate S causes the processing liquid to spread to an outer side of the liquid adhesion position by the action of centrifugal force, resulting in removal of the thin film located on an outer side of the liquid adhesion position.

The shaft-shaped part 52b is located on a radially inner side of the substrate S in the nozzle body 52, that is, on an opposite side from the discharge port 521, and extends toward a radially inner side. The shaft-shaped part 52b is inserted into and supported by a bearing 533 provided in the nozzle driving part 53.

The nozzle driving part 53 includes a motor (actuator) 531, a shaft 532, a bearing 533 supporting the shaft-shaped part 52b of the nozzle body 52, and a housing 534. The motor 531 is retained by a motor holder 535 except for a side of the surface to which the shaft 532 is attached and which faces a radially outer side. The motor 531 is, for example, a stepping motor.

The shaft 532 is cantilevered by the motor 531, and is provided integrally with the motor 531. One end of the shaft 532 is connected to the shaft-shaped part 52b of the nozzle body 52, and the other end of the shaft 532 is connected to the motor 531. The one end of the shaft 532 is engaged with the shaft-shaped part 52b.

Specifically, the shaft-shaped part 52b of the nozzle body 52 has a shaft hole 523 that has an opening facing a radially inner side from which the shaft 532 is inserted and that extends toward a radially outer side, and a nut 524 is fixed to this shaft hole 523. The shaft 532 has, on an outer periphery thereof, a thread to be screwed with the nut 524, and the thread provided on the outer periphery of the shaft 532 is screwed with the nut 524, so that the shaft 532 is engaged with the shaft-shaped part 52b.

This causes the nut 524 screwed with the outer periphery of the shaft 532 to move in a radial direction of the substrate S when the shaft 532 rotates by the driving of the motor 531. A direction of the movement depends on a direction of the rotation of the shaft 532, and an amount of the movement depends on the rotational amount of the shaft 532. The movement of the nut 524 along a radial direction of the substrate S causes the nozzle body 52 to which the nut 524 is fixed to move along the radial direction of the substrate S.

In this case, while rotating by the driving of the motor 531, the shaft 532 advances and retracts in a radial direction of the substrate S as one example of a predetermined direction. Further, since the rotation of the shaft 532 causes the nozzle body 52 fixed with the nut 524 to move in a radial direction of the substrate S, the shaft 532 advances and retracts in a radial direction of the substrate S relative to the nozzle body 52. That is, the shaft 532 advances and retracts in a radial direction of the substrate S within the shaft hole 523 included in the shaft-shaped part 52b of the nozzle body 52. While being guided by the shaft 532, the nozzle body 52 moves in a radial direction of the substrate S.

The housing 534 fixes and accommodates the motor 531 and the bearing 533. The housing 534 not only fixes the motor 531 and the bearing 533 but also accommodates the motor 531 and the bearing 533 so as to cover at least a portion lying from a side of the motor 531 to which the shaft 532 is connected, to the bearing 533.

The bearing 533 is provided so as to be able to support the shaft-shaped part 52b with the nozzle body 52 positioned on a radially outermost side. The bearing 533, which is provided so as to extend from an end part 531E of the motor 531 in a direction in which the shaft 532 advances and retracts, accommodates therein the shaft 532 and has an inner peripheral surface 533F on which the nozzle body 52 slides. The end part 531E is an end part, located on a radially outer side of the substrate S, of a part surrounding the periphery of a rotation shaft part 531A included in the motor 531. It should be noted that some configurations of the bearing 533 are not illustrated in FIGS. 5 and 6.

The nozzle driving part 53 causes the nozzle body 52 to reciprocate in a radial direction of the substrate S with use of the motor 531, so that it is possible to adjust the position of the nozzle body 52. This makes it possible to change the position in which the processing liquid discharged from the discharge port 521 provided in the nozzle body 52 adheres to the substrate S, to adjust an etching width.

The bearing 533 is a sleeve bearing 533A extending in a radial direction of the substrate S. The sleeve bearing 533A has a radially outer end part located in a position that allows supporting of the shaft-shaped part 52b with the nozzle body 52 positioned on a radially outermost side of the substrate S, and extends from this position toward a radially inner side.

The shaft-shaped part 52b is inserted from a radially outer end part of the sleeve bearing 533A, and the shaft 532 is inserted from a radially inner end part of the sleeve bearing 533A. The shaft-shaped part 52b is engaged with the shaft 532 in the sleeve bearing 533A.

Examples of the sleeve bearing include Iglidur G (product name: available from Igus Co., Ltd.), which is a slide bearing. Note that it is preferable to use a sleeve bearing as the bearing 533 from the above-described aspect, but this should not be construed as a limitation. For example, a configuration may be employed in which roller bearings are disposed at a plurality of locations.

The motor 531 and the bearing 533 are fixed to the housing 534 by interference fit. To be precise, since the motor 531 is retained by the motor holder 535, the motor 531 is fixed together with the bearing 533 by the housing 534 by interference fit while being retained by the motor holder 535.

Further, on a radially outer side of the bearing 533, a sealing ring 536 that seals an annular space between the bearing 533 and the shaft-shaped part 52b is disposed. An annular groove 534a into which the sealing ring 536 is disposed is formed in the housing 534, and the sealing ring 536 is fitted into this groove 534a. An annular retaining member 537 is fitted on a radially outer side of the sealing ring 536 to prevent the sealing ring 536 from falling off.

The center axis of the motor 531, the center axis of the shaft 532, and the center axis of the bearing 533 are aligned. In other words, the center axis of the motor 531, the center axis of the shaft 532, and the center axis of the bearing 533 are disposed coaxially.

The processing liquid discharge nozzle parts 51 (51A to 51C) and the support base 54 are each made of a material excellent in chemical resistance, for example, a resin material. For example, polyethylene resin, polytetrafluoroethylene (PTFE) resin, polyetheretherketone (PEEK) resin, or the like can be selected for use as appropriate according to the objective.

### Pressure sensor

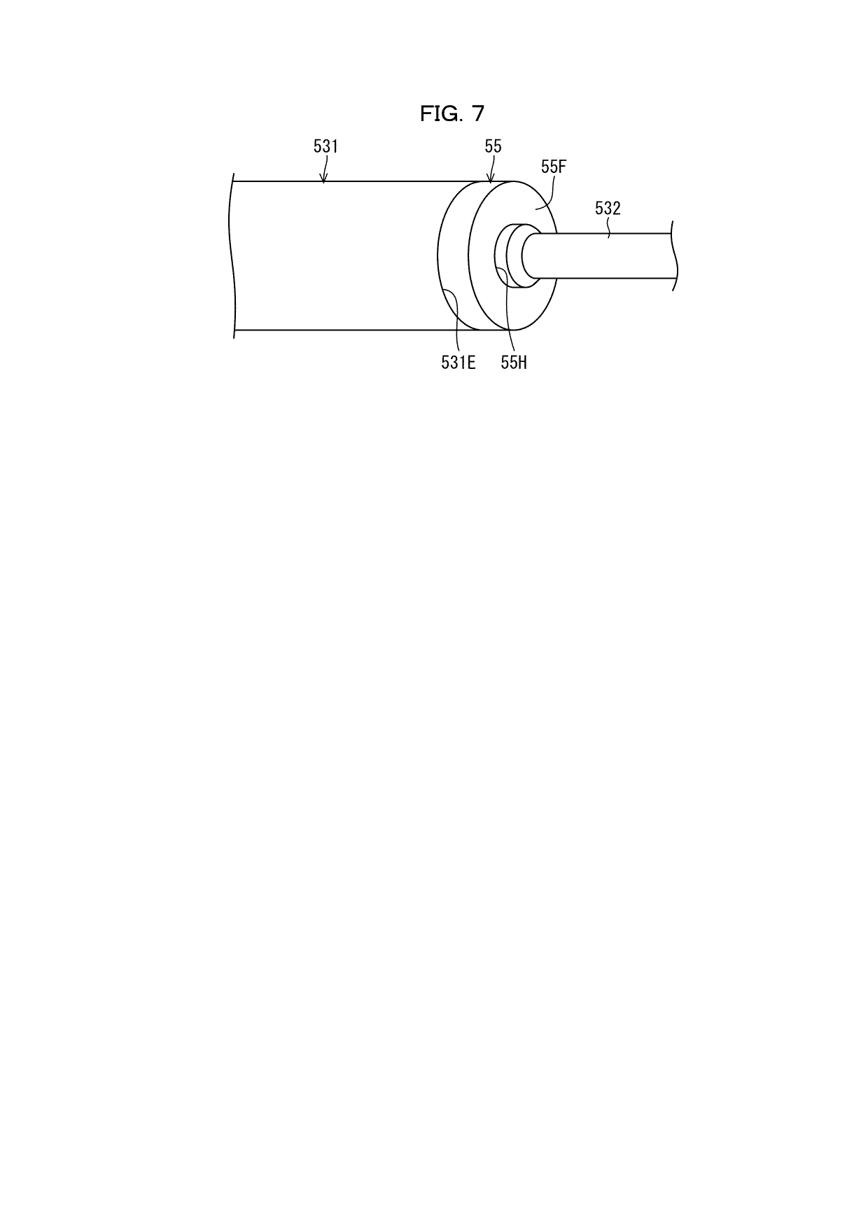

FIG. 7 is a perspective view illustrating a configuration in the vicinity of a pressure sensor 55 included in the processing mechanism 5. The nozzle block 50 has the pressure sensor 55 illustrated in FIGS. 5 to 7. The pressure sensor 55 obtains a pressure value caused between the motor 531 and the nozzle body 52 by the movement of the nozzle body 52 in a radial direction of the substrate S while the nozzle body 52 is being guided by the shaft 532. Specifically, the pressure sensor 55 obtains a pressure value caused between the end part 531E of the motor 531 and the shaft-shaped part 52b.

The pressure sensor 55 has a flat surface 55F orthogonal to an axial direction of the shaft 532, and has a plurality of pressure detection points on the flat surface 55F. The flat surface 55F is a flat surface of the pressure sensor 55 located on a radially outer side of the substrate S. The plurality of pressure detection points are, for example, a plurality of pressure-sensitive sensors. For example, the plurality of pressure detection points may be positioned concentrically on the flat surface 55F or may be positioned in matrix on the flat surface 55F.

The pressure sensor 55 obtains a pressure value at each of the plurality of pressure detection points. That is, the pressure sensor 55 obtains a distribution of the pressure on the flat surface 55F. The pressure sensor 55 may have a single pressure detection point.

A through hole 55H through which the shaft 532 passes is formed in the pressure sensor 55, and the pressure sensor 55 is provided at the end part 531E of the motor 531 from which the shaft 532 protrudes. The pressure sensor 55 is disposed in the vicinity of the boundary between the end part 531E and the other end of the shaft 532. The pressure sensor 55 has a substantially annular shape and is disposed so as to surround the other end of the shaft 532. The pressure sensor 55 is provided in and accommodated in the bearing 533.

### Control unit

As illustrated in FIG. 2, the control unit 10 includes a driving control part 101, a data obtaining part 102, and an origin position detection part 103. The origin position detection part 103 has an abnormality detection part 104.

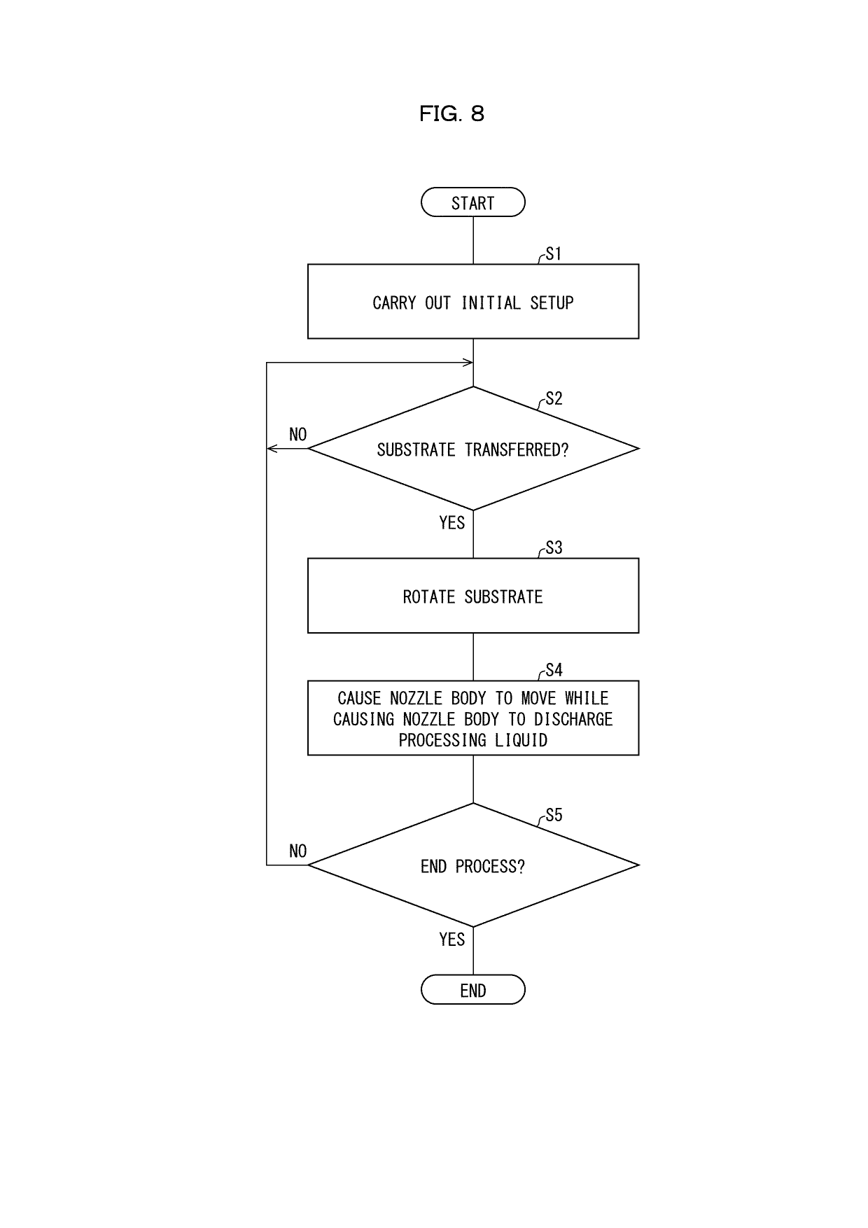

FIG. 8 is a flowchart illustrating one example of a process in which the control unit 10 included in the processing unit 1 causes the nozzle body 52 to discharge a processing liquid. As illustrated in FIG. 8, the control unit 10 carries out initial setup (S1). The initial setup will be described later in detail. After the control unit 10 has carried out the initial setup, the driving control part 101 determines whether or not a substrate S has been transferred to a processing unit 1 (S2). In a case where the driving control part 101 has determined that the substrate S has not been transferred (NO in S1), the driving control part 101 continues the process of step S2.

In a case where the driving control part 101 has determined that a substrate S has been transferred (YES in S1), the driving control part 101 causes the retaining and rotating mechanism 2 to rotate the substrate S (S3). While carrying out the process of step S3, the driving control part 101 causes the nozzle body 52 to move from its origin position with use of the motor 531 and causes the nozzle body 52 to discharge a processing liquid (S4).

Subsequently, the driving control part 101 determines whether to end the process of discharging the processing liquid to the substrate S (S5). In a case where the driving control part 101 has determined to end the process of discharging the processing liquid to the substrate S (YES in S5), the driving control part 101 ends the process of discharging the processing liquid to the substrate S. In a case where the driving control part 101 has determined not to end the process of discharging the processing liquid to the substrate S (NO in S5), the process by the driving control part 101 transitions to step S2.

Movement to origin position

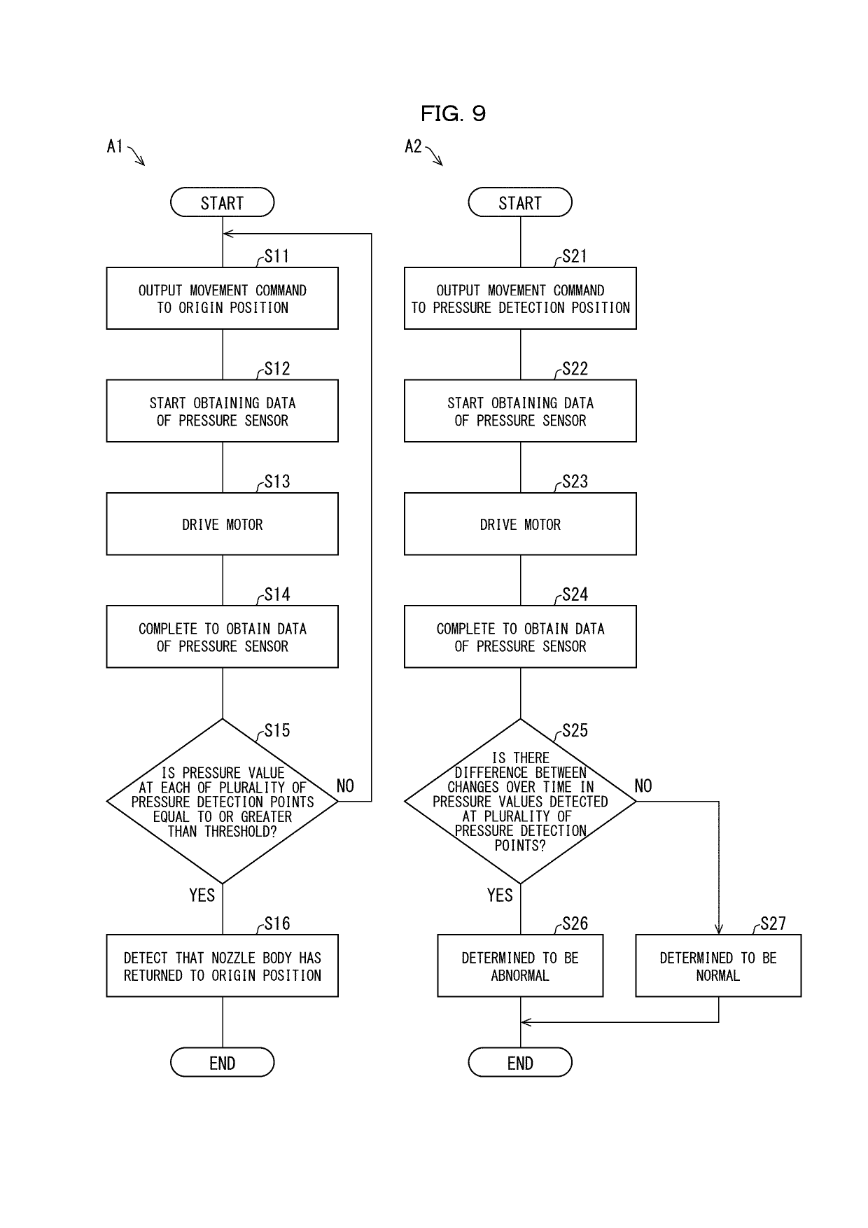

FIG. 9 is a flowchart illustrating one example of a process in which the control unit 10 included in a processing unit 1 causes the nozzle body 52 to move. The reference sign A1 in FIG. 9 represents a flowchart illustrating one example of a process, which is carried out by the control unit 10 as the initial setup of step S1, of causing the nozzle body 52 to return to its origin position. The origin position is a position where the shaft-shaped part 52b of the nozzle body 52 is brought into contact with the pressure sensor 55.

As illustrated in the reference sign A1 of FIG. 9, the control unit 10 outputs a movement command for the nozzle body 52 to move to its origin position (S11). The movement command instructs that the nozzle body 52 move to the origin position.

After the control unit 10 has outputted the movement command to the origin position, the data obtaining part 102 starts obtaining data of the pressure sensor 55 (S12). At this time, the data obtaining part 102 obtains the pressure values at the plurality of pressure detection points of the pressure sensor 55 from the pressure sensor 55. After the data obtaining part 102 has started obtaining the data of the pressure sensor 55, the driving control part 101 drives the motor 531 on the basis of the movement command in step S11 (S13). In step S13, the motor 531 causes the nozzle body 52 to move to the origin position.

Subsequently, the data obtaining part 102 completes to obtain the data of the pressure sensor 55 (S14). After the data obtaining part 102 has completed to obtain the data of the pressure sensor 55, the origin position detection part 103 determines whether or not each of the pressure values at the plurality of pressure detection points of the pressure sensor 55 is equal to or greater than a predetermined threshold (S15). In step S15, the origin position detection part 103 may determine whether or not a pressure value at each of at least two pressure detection points included in the plurality of pressure detection points is equal to or greater than the threshold.

In a case where the origin position detection part 103 has determined that a pressure value at at least one pressure detection point of the plurality of pressure detection points of the pressure sensor 55 is less than the threshold (NO in S15), the process by the control unit 10 transitions to the process of step S11. In a case where the origin position detection part 103 has determined that the pressure value at each of the plurality of pressure detection points of the pressure sensor 55 is equal to or greater than the threshold (YES in S15), the origin position detection part 103 detects that the nozzle body 52 has returned to the origin position (S16). After the origin position detection part 103 has detected that the nozzle body 52 has returned to its origin position, the process by the control unit 10 transitions to step S2.

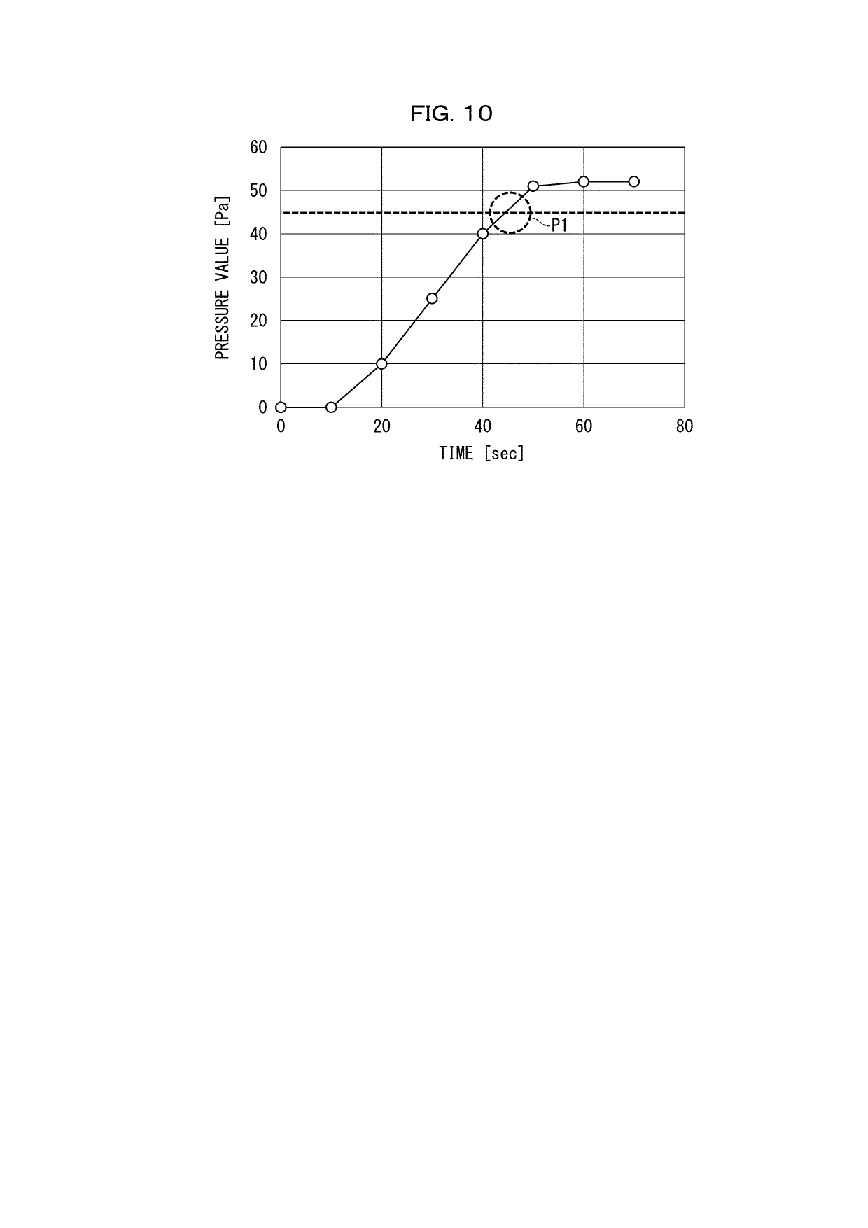

FIG. 10 is a graph illustrating one example of a relationship between time and a pressure value obtained by the pressure sensor 55. In FIG. 10, the horizontal axis represents time [sec] and the vertical axis represents a pressure value [Pa]. When the driving control part 101 drives the motor 531 in step S13, the pressure value increases over time. Here, in step S16, as indicated by the reference sign P1 in FIG. 10, when the pressure value becomes equal to or greater than 45 Pa, which is one example of the threshold, the origin position detection part 103 detects that the nozzle body 52 has returned to the origin position.

In this way, when the pressure values obtained by the pressure sensor 55 each become equal to or greater than a predetermined threshold, the origin position detection part 103 detects that the nozzle body 52 has returned to its origin. Here, since the space between the motor 531 and the nozzle body 52 has design flexibility, the pressure sensor 55 can be designed into a desired shape, and thus it is possible to downsize the configuration of the processing unit 1. For example, the pressure sensor 55 can be designed to have a thin, small size.

According to step S16, when the pressure value at each of at least two pressure detection points included in the plurality of pressure detection points are each equal to or greater than a predetermined threshold, the origin position detection part 103 detects that the nozzle body 52 has returned to the origin position. By using results of the detection at the plurality of pressure detection points, it is possible to accurately detect that the nozzle body 52 has returned to the origin position. Further, it is possible to check whether the shaft-shaped part 52b of the nozzle body 52 is evenly in contact with the pressure sensor 55.

As described above, the through hole 55H through which the shaft 532 passes is formed in the pressure sensor 55, and the pressure sensor 55 is provided at the end part 531E of the motor 531 from which the shaft 532 protrudes. This allows the origin position detection part 103 to reliably detect that the nozzle body 52 has returned to its origin, in step S16.

### Movement to pressure detection position

The reference sign A2 in FIG. 9 represents a flowchart illustrating one example of a process, which is carried out by the control unit 10 as the initial setup of step S1, of causing the nozzle body 52 to move to a pressure detection position. The pressure detection position is, for example, the origin position. The process of step S21 indicated by the reference sign A2 in FIG. 9 may be the same as the process of step S11 indicated by the reference sign A1 in FIG. 9.

The processes of steps S22 to S24 indicated by the reference sign A2 in FIG. 9 are respectively in this order the same as the processes of steps S12 to S14 indicated by the reference sign A1 in FIG. 9. The control unit 10 carries out the processes of steps S25 to S27 indicated by the reference sign A2 in FIG. 9 in parallel with the processes of steps S15 and S16 illustrated in the reference sign A1 in FIG. 9.

As indicated by the reference sign A2 in FIG. 9, after in step S24, the data obtaining part 102 has completed to obtain the data of the pressure sensor 55, the abnormality detection part 104 included in the origin position detection part 103 determines whether there is a difference between changes over time in the pressure values detected at the plurality of pressure detection points (S25). In step S25, the abnormality detection part 104 may determine whether there is a difference between changes over time in the pressure values at at least two pressure detection points included in the plurality of pressure detection points.

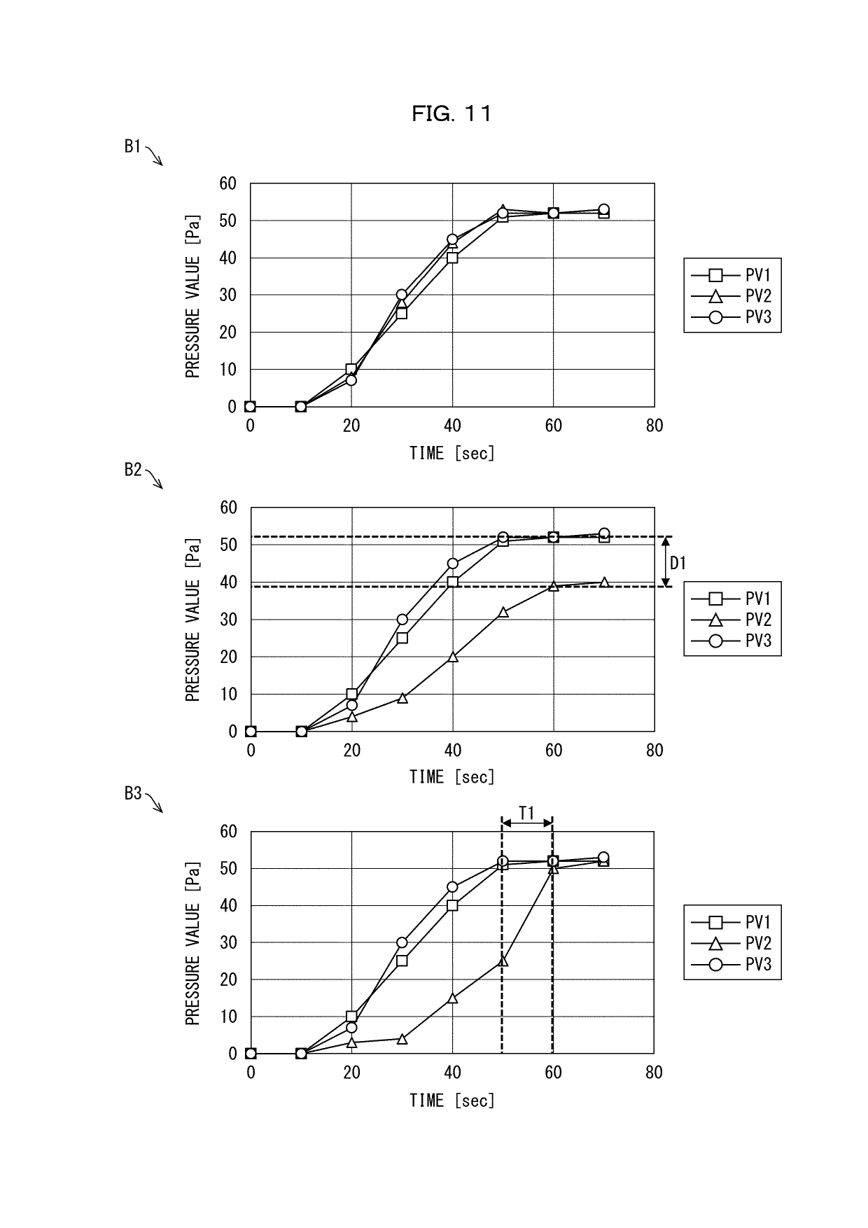

FIG. 11 is each graph illustrating one example of a relationship between time and pressure values at a plurality of pressure detection points obtained by the pressure sensor 55. In FIG. 11, the horizontal axis represents time [sec] and the vertical axis represents a pressure value [Pa].

FIG. 11 shows a pressure value PV1 at a first pressure detection point, a pressure value PV2 at a second pressure detection point, and a pressure value PV3 at a third pressure detection point. The first pressure detection point, the second pressure detection point, and the third pressure detection point are included in the plurality of pressure detection points of the pressure sensor 55. When the driving control part 101 drives the motor 531 in step S23, the pressure value increases over time.

For example, in the case indicated by the reference sign B1 in FIG. 11, the abnormality detection part 104 determines that there is no difference between changes over time in the pressure values PV1, PV2, and PV3 detected respectively at the first pressure detection point, the second pressure detection point, and the third pressure detection point.

The following will consider, for example, a case where as indicated by the reference sign B2 in FIG. 11, a significant difference D1 is found between the pressure value PV2 detected at the second pressure detection point and the pressure values PV1 and PV3 detected at the same time with the pressure value PV2 at the first pressure detection point and the third pressure detection point. In this case, the abnormality detection part 104 determines that there is a difference between changes over time in the pressure values PV1, PV2, and PV3.

That is, in a case where a significant difference is found between a pressure value at any one of the plurality of pressure detection points and a pressure value detected at the same time at another pressure detection point, the abnormality detection part 104 determines that there is a difference between changes over time in the pressure values detected at the plurality of pressure detection points.

In addition, the following will consider, for example, a case where as indicated by the reference sign B3 in FIG. 11, a significant difference is found between a change rate of the pressure value PV2 in a specific period T1 detected at the second pressure detection point and change rates of the pressure values PV1 and PV3 in the specific period T1 detected at the first pressure detection point and the third pressure detection point. In this case, the abnormality detection part 104 determines that there is a difference between changes over time in the pressure values PV1, PV2, and PV3. The change rate refers to a ratio of the pressure value to the specific period T1. The specific period T1 is, for example, a period between time points at which pressure values temporally adjacent to each other are obtained.

As described above, in a case where a significant difference is found between a change rate of a pressure value in a specific period detected at any one of the plurality of pressure detection points and a change rate of a pressure value in the specific period detected at another pressure detection point, the abnormality detection part 104 determines that there is a difference between changes over time in the pressure values detected at the plurality of pressure detection points.

In a case where the abnormality detection part 104 has determined that there is a difference between changes over time in the pressure values detected at the plurality of pressure detection points (YES in S25), the abnormality detection part 104 determines that the advancing and retracting of the shaft 532 involve an abnormality (S26). In this case, the control unit 10 causes an unillustrated alarm output part to output an alarm.

Through steps S25 and S26, it is possible to accurately determine abnormalities occurring in the advancing and retracting of the shaft 532. Examples of the abnormalities in the advancing and retracting of the shaft 532 include distortion of the shaft 532 and deviation of the shaft 532 from the center axis of the motor 531. The distortion and deviation occur due to aging over time of the shaft 532 or an impact of heat applied to the shaft 532.

In a case where the pressure detection position is the origin position in step S21, and YES in step S25, the abnormality detection part 104 may determine that returning of the nozzle body 52 to the origin position involves an abnormality. This makes it possible to accurately determine abnormalities occurring during return of the nozzle body 52 to the origin position.

In a case where the abnormality detection part 104 has determined that there is no difference between changes over time in the pressure values detected at the plurality of pressure detection points (NO in S25), the advancing and retracting of the shaft 532 is determined to be normal (S27). In a case where the pressure detection position is the origin position in step S21, and NO in step S25, the abnormality detection part 104 may determine that the returning of the nozzle body 52 to the origin position is normal. After the abnormality detection part 104 has determined that the advancing and retracting of the shaft 532 is normal, the process by the control unit 10 transitions to step S2.

In this way, the abnormality detection part 104 detects abnormalities in the advancing and retracting of the shaft 532 on the basis of the pressure value at each of at least two pressure detection points included in the plurality of pressure detection points. As described above, by using the detection results at the plurality of pressure detection points, it is possible to accurately detect abnormalities in the advancing and retracting of the shaft 532.

### Variation 1

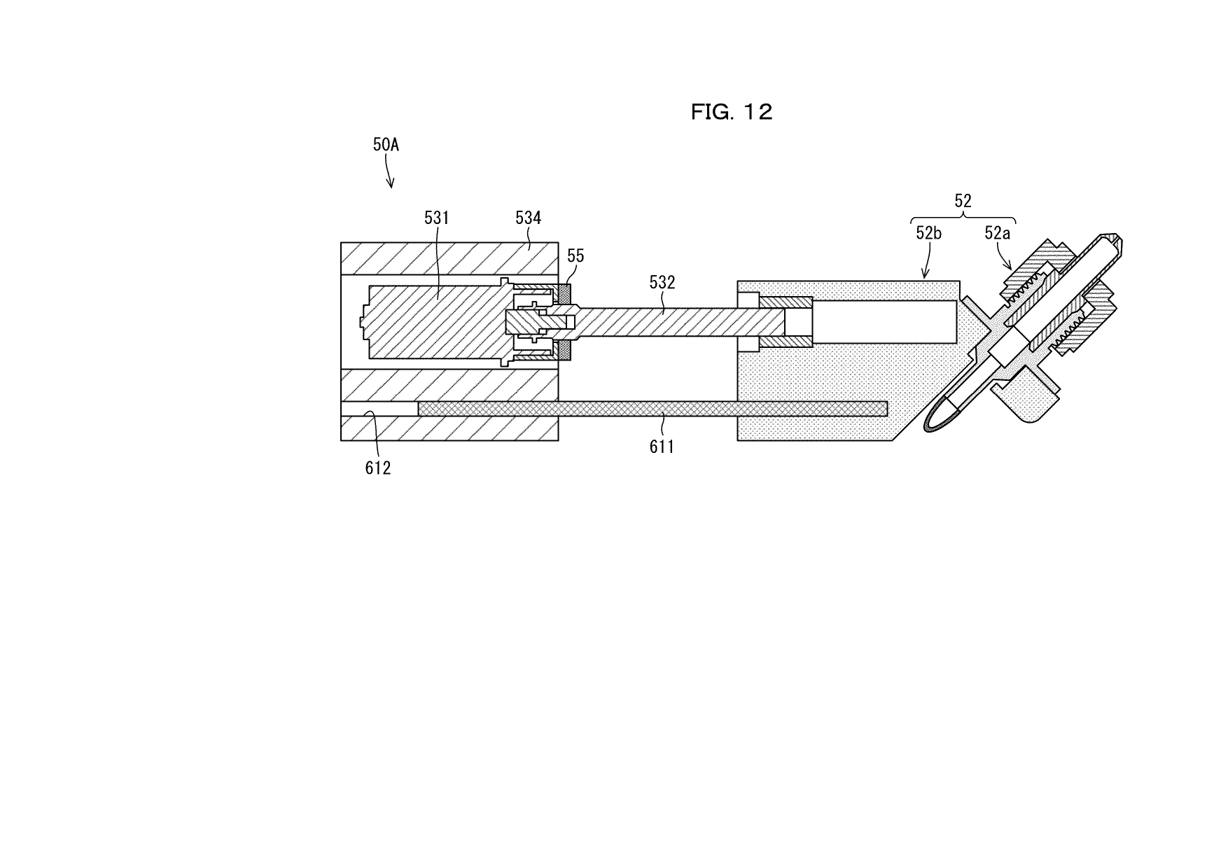

FIG. 12 is a cross-sectional view illustrating a nozzle block 50A included in a processing unit in accordance with variation 1 of the present invention. The processing unit in accordance with variation 1 includes the nozzle block 50A as a configuration corresponding to the nozzle block 50. As illustrated in FIG. 12, the nozzle block 50A includes the nozzle body 52, the motor 531, the shaft 532, the housing 534, and a support shaft 611. It should be noted that in FIG. 12, the support base 54, the bearing 533, the sealing ring 536, and the retaining member 537 are not illustrated.

The support shaft 611 is configured to assist in supporting the nozzle body 52. One end of the support shaft 611 is fixed to the shaft-shaped part 52b of the nozzle body 52, and the other end of the support shaft 611 is connected to the housing 534.

The housing 534 has a shaft hole 612, and the support shaft 611 has a thread at an outer periphery thereof. The thread of the support shaft 611 is screwed with the thread provided in the shaft hole 612, so that the support shaft 611 is engaged with the housing 534. Therefore, when the motor 531 rotates the shaft 532 to cause the nozzle body 52 to move in a radial direction of the substrate S, the support shaft 611 moves accordingly in a radial direction of the substrate S.

### Variation 2

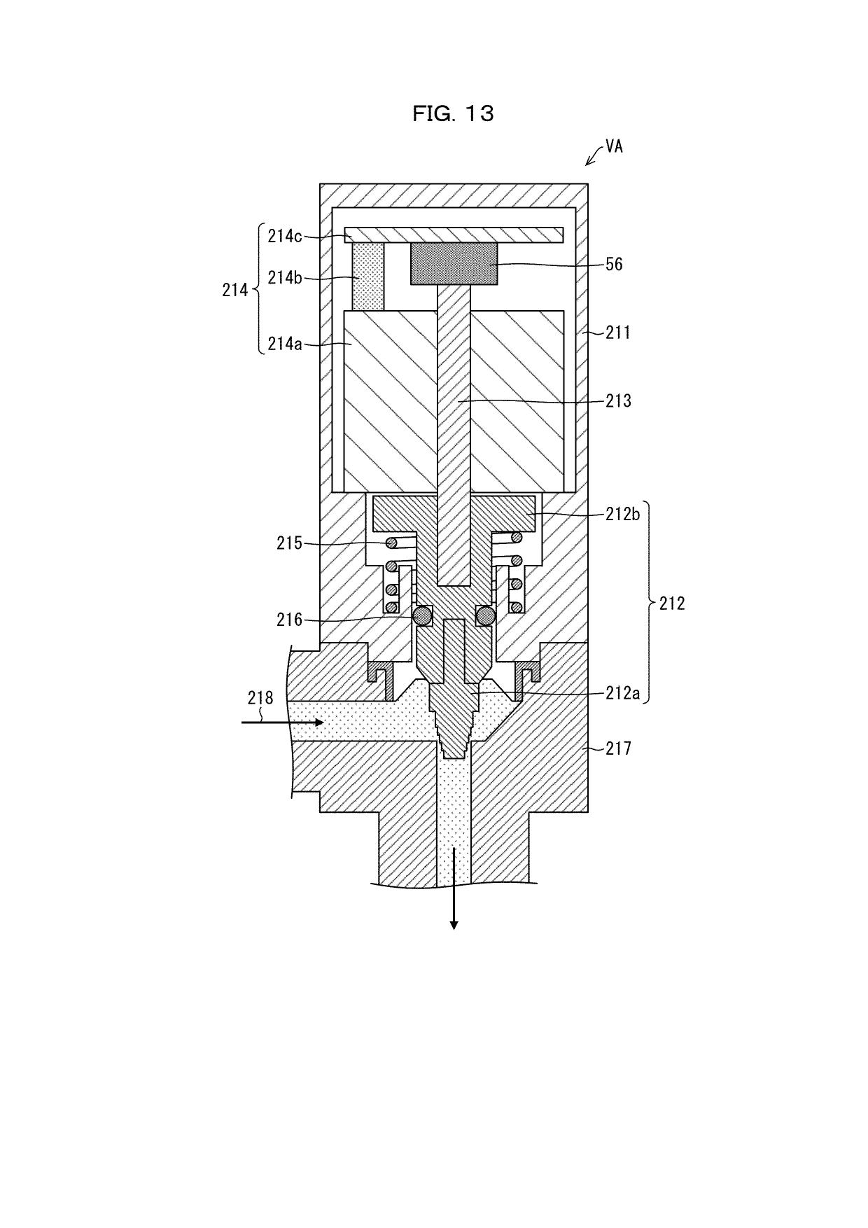

FIG. 13 is a cross-sectional view illustrating an example of an open/close valve VA included in a processing unit in accordance with variation 2 of the present invention. As illustrated in FIG. 13, the open/close valve VA includes a housing 211, an open/close part 212, a shaft 213, an actuator 214, and a pressure sensor 56. The open/close valve VA is a needle valve.

The open/close valve VA is provided in a pipe 217, and opens and closes a flow path 218 of the pipe 217 through which the processing liquid flows, in accordance with a control signal from the driving control part 101 (described later) of an unillustrated control unit included in the processing unit. The pipe 217 guides the processing liquid to an unillustrated supply part that supplies the processing liquid to the substrate S. The supply part is, for example, the nozzle body 52.

The housing 211 accommodates therein the shaft 213, the actuator 214, and the pressure sensor 56. The open/close part 212 opens and closes the flow path 218 of the pipe 217 that guides the processing liquid to the supply part that supplies the processing liquid to the substrate S. That is, the open/close part 212 is one example of a surface processing mechanism configured to carry out a predetermined surface treatment on the substrate S. The open/close part 212 has a diaphragm 212a and a connection part 212b. The diaphragm 212a is made of a plastic member, such as resin.

The connection part 212b connects the diaphragm 212a and the shaft 213. A groove portion formed in the connection part 212b is provided with a sealing ring 216 that seals the space between the connecting part 212b and the housing 211. A spring 215 is provided between the connection part 212b and the housing 211. One end of the shaft 213 is connected to the connection part 212b, and the other end of the shaft 213 is connected to a motor 214a of the actuator 214.

The actuator 214 includes the motor 214a, a connection part 214b, and a support part 214c. The motor 214a is connected to the other end of the shaft 213 and causes the shaft 213 to advance and retract. The shaft 213 advances and retracts by driving of the motor 214a in, as one example of a predetermined direction, a direction for causing the open/close part 212 to open and close the flow path 218. That is, the shaft 213 advances and retracts in a direction in which the actuator 214 and the open/close part 212 are arranged.

The connection part 214b connects the motor 214a and the support part 214c. The support part 214c supports the pressure sensor 56. The shaft 213 advances and retracts by the driving of the motor 214a, thereby changing a distance between the shaft 213 and the support part 214c.

The pressure sensor 56 obtains, at a plurality of pressure detection points, pressure values caused between the support part 214c and the shaft 213 when the open/close part 212 moves, while being guided by the shaft 213, in a direction in which the flow path 218 is opened. The pressure sensor 56 may differ from the pressure sensor 55 in that the through hole 55H is not formed in the pressure sensor 56 and in that the shape of the pressure sensor 56 is not substantially annular.

As in the case of the control unit 10, the control unit included in the processing unit in accordance with variation 2 includes the driving control part 101, the data obtaining part 102, and the origin position detection part 103. In this case, the functions of the driving control part 101, the data obtaining part 102, and the origin position detection part 103 included in the control unit in accordance with variation 2 may be the same as those of the driving control part 101, the data obtaining part 102, and the origin position detection part 103 included in the control unit 10.

### Software implementation example

Functions of each processing unit 1 (hereinafter, referred to as "apparatus") can be realized by a program for causing a computer to function as the apparatus, the program causing the computer to function as each control block (in particular, each component included in the control unit 10) of the apparatus.

In this case, the apparatus includes, as hardware configured to execute the program, a computer that includes at least one controller (e.g., a processor such as a CPU) and at least one storage apparatus (e.g., a memory). By executing the program with the controller and the storage apparatus, the functions described in the above embodiment are realized.

The program can be stored in at least one computer-readable non-transitory storage medium. The storage medium can be provided in the apparatus, or the storage medium does not need to be provided in the apparatus. In the latter case, the program can be supplied to the apparatus via any wired or wireless transmission medium.

Further, some or all of the functions of the control blocks described above can be realized by a logic circuit. For example, an integrated circuit in which a logic circuit that functions as each control block described above is formed is also within the scope of the present invention.

Aspects of the present invention can also be expressed as follows:

A substrate processing apparatus in accordance with an aspect of the present invention includes: a rotator configured to retain a substrate with a circular shape in a horizontal position and rotate the substrate about a vertical axis passing the center of the substrate; a nozzle body disposed below the substrate and configured to discharge a processing liquid from a discharge port thereof toward a peripheral portion of a lower surface of the substrate; a shaft having one end connected to the nozzle body and the other end connected to an actuator, the shaft advancing and retracting in a radial direction of the substrate by driving of the actuator; a pressure sensor configured to obtain a pressure value caused between the actuator and the nozzle body by movement of the nozzle body in the radial direction of the substrate while the nozzle body is being guided by the shaft; and an origin position detection part configured to, when the pressure value becomes equal to or greater than a predetermined threshold, detect that the nozzle body has returned to an origin thereof.

A substrate processing apparatus in accordance with an aspect of the present invention may be configured such that: the pressure sensor has a flat surface orthogonal to an axial direction of the shaft and has a plurality of pressure detection points on the flat surface; and when a pressure value at each of at least two pressure detection points included in the plurality of pressure detection points becomes equal to or greater than the predetermined threshold, the origin position detection part detects that the nozzle body has returned to a position of the origin.

A substrate processing apparatus in accordance with an aspect of the present invention may be configured such that in a case where there is a difference between changes over time in pressure values detected at the plurality of pressure detection points, the origin position detection part determines that returning of the nozzle body to the position of the origin involves an abnormality.

A substrate processing apparatus in accordance with an aspect of the present invention may be configured such that a through hole through which the shaft passes is formed in the pressure sensor, and the pressure sensor is provided at an end part of the actuator from which the shaft protrudes.

A substrate processing apparatus in accordance with an aspect of the present invention may further include a bearing provided so as to extend in a direction in which the shaft advances and retracts from the end part of the actuator, the bearing accommodating therein the shaft and having an inner peripheral surface on which the nozzle body slides, and the pressure sensor may be accommodated in the bearing.

A substrate processing apparatus in accordance with an aspect of the present invention may be configured such that a center axis of the actuator, a center axis of the shaft, and a center axis of the bearing are aligned.

A substrate processing method in accordance with an aspect of the present invention includes: using a rotator to, while retaining a substrate with a circular shape in a horizontal position, rotate the substrate about a vertical axis passing the center of the substrate; causing a shaft to advance and retract in a radial direction of the substrate by driving of an actuator, the shaft having one end connected to a nozzle body disposed below the substrate so that a processing liquid is discharged from a discharge port thereof toward a peripheral portion of a lower surface of the substrate and the other end connected to the actuator; and obtaining, with use of a pressure sensor, a pressure value caused between the actuator and the nozzle body by movement of the nozzle body in the radial direction of the substrate while the nozzle body is being guided by the shaft, the nozzle body being, when the pressure value becomes equal to or greater than a predetermined threshold, detected to have returned to an origin thereof.

### Additional remarks

The present invention is not limited to the embodiment described above, but may be altered in various ways by a skilled person within the scope of the claims. Specifically, any embodiment based on a proper combination of a plurality of technical means disclosed in the embodiment is also encompassed in the technical scope of the present invention.

### Reference Signs List

1 Processing unit

2 Retaining and rotating mechanism

10 Control unit

531 Motor

531E End part

52 Nozzle body

55, 56 Pressure sensor

55F Flat surface

55H Through hole

103 Origin position detection part

104 Abnormality detection part

212 Open/close part

213, 532 Shaft

214 Actuator

533 Bearing

533F Inner peripheral surface

D1 Significant difference

T1 Specific period

S Substrate

1. A substrate processing apparatus comprising:
a rotator configured to retain a substrate with a circular shape in a horizontal position and rotate the substrate about a vertical axis passing the center of the substrate;
a nozzle body disposed below the substrate and configured to discharge a processing liquid from a discharge port thereof toward a peripheral portion of a lower surface of the substrate;
a shaft having one end connected to the nozzle body and the other end connected to an actuator, the shaft advancing and retracting in a radial direction of the substrate by driving of the actuator;
a pressure sensor configured to obtain a pressure value caused between the actuator and the nozzle body by movement of the nozzle body in the radial direction of the substrate while the nozzle body is being guided by the shaft; and
an origin position detection part configured to, when the pressure value becomes equal to or greater than a predetermined threshold, detect that the nozzle body has returned to an origin thereof.

2. The substrate processing apparatus according to claim 1, wherein:
the pressure sensor has a flat surface orthogonal to an axial direction of the shaft and has a plurality of pressure detection points on the flat surface; and
when a pressure value at each of at least two pressure detection points included in the plurality of pressure detection points becomes equal to or greater than the predetermined threshold, the origin position detection part detects that the nozzle body has returned to a position of the origin.

3. The substrate processing apparatus according to claim 2, wherein in a case where there is a difference between changes over time in pressure values detected at the plurality of pressure detection points, the origin position detection part determines that returning of the nozzle body to the position of the origin involves an abnormality.

4. The substrate processing apparatus according to claim 1, wherein a through hole through which the shaft passes is formed in the pressure sensor, and the pressure sensor is provided at an end part of the actuator from which the shaft protrudes.

5. The substrate processing apparatus according to claim 4, further comprising a bearing provided so as to extend in a direction in which the shaft advances and retracts from the end part of the actuator, the bearing accommodating therein the shaft and having an inner peripheral surface on which the nozzle body slides,
the pressure sensor being accommodated in the bearing.

6. The substrate processing apparatus according to claim 5, wherein a center axis of the actuator, a center axis of the shaft, and a center axis of the bearing are aligned.

7. A substrate processing method comprising:
using a rotator to, while retaining a substrate with a circular shape in a horizontal position, rotate the substrate about a vertical axis passing the center of the substrate;
causing a shaft to advance and retract in a radial direction of the substrate by driving of an actuator, the shaft having one end connected to a nozzle body disposed below the substrate so that a processing liquid is discharged from a discharge port thereof toward a peripheral portion of a lower surface of the substrate and the other end connected to the actuator; and
obtaining, with use of a pressure sensor, a pressure value caused between the actuator and the nozzle body by movement of the nozzle body in the radial direction of the substrate while the nozzle body is being guided by the shaft,
the nozzle body being, when the pressure value becomes equal to or greater than a predetermined threshold, detected to have returned to an origin thereof.
